(19) United States
(12) Patent Application Publication
(10) Pub. No.: US 2020/0344890 A1
(43) Pub. Date: Oct. 29, 2020

(54) METHOD OF MANUFACTURING SUBSTRATE FOR PRINTED CIRCUIT BOARD

(71) Applicant: SUMITOMO ELECTRIC INDUSTRIES, LTD., Osaka (JP)

(72) Inventors: Motohiko SUGIURA, Osaka (JP); Issei OKADA, Osaka (JP)

(21) Appl. No.: 16/958,870

(22) PCT Filed: Oct. 30, 2018
(86) PCT No.: PCT/JP2018/040288

§ 371 Date: Jun. 29, 2020

(30) Foreign Application Priority Data
Jan. 18, 2018 (JP) 2018-006681

(51) Int. Cl. H05K 3/12; H05K 3/38

(52) U.S. Cl. CPC H05K 3/1283; H05K 2203/1131; H05K 2203/1121; H05K 3/38

(57) ABSTRACT

According to one aspect of the present disclosure, a method of manufacturing a substrate for a printed circuit board, including an insulating base film and a metal layer that is layered on at least one surface side of the base film, includes: an application step of applying, to the at least one surface side of the base film, a dispersion liquid containing fine metal particles; a drying step of drying a coating film of the applied dispersion liquid; a sintering step of sintering the dried coating film by a far-infrared heater under a low oxygen atmosphere with an oxygen concentration of 600 ppm by volume or less; and a cooling step of cooling a layered structure of the sintered coating film and the base film under a low oxygen atmosphere with an oxygen concentration of 600 ppm by volume or less.

### TECHNICAL FIELD

The present disclosure relates to a method of manufacturing a substrate for a printed circuit board. The present application is based on and claims priority to Japanese Patent Application No. 2018-006681, filed on Jan. 18, 2018, the entire contents of the Japanese Patent Application are hereby incorporated herein by reference.

### BACKGROUND ART

In order to manufacture a printed circuit board, a substrate for a printed circuit board in which a metal layer formed of, for example, copper or the like is layered on the surface of an insulating base film formed of, for example, a resin or the like is widely used.

A printed circuit board is manufactured by a method such as a subtractive method in which a resist pattern is formed on a metal layer of a substrate for a printed circuit board to selectively remove the metal layer exposed from the resist pattern by etching or a semi-additive method in which a resist pattern is formed on a metal layer and a metal is further layered on the metal layer exposed from the resist pattern by electroplating.

Known methods of manufacturing a substrate for a printed circuit board as described above include, for example, adhesion of a metal foil to a base film, deposition of a metal, sputtering, plating, applying and sintering of a fine metal particle dispersion liquid, and the like. In particular, the applying and sintering of a fine metal particle dispersion liquid, which does not require large-scale equipment, such as a vacuum device, and which can form a metal layer relatively easily and inexpensively, has attracted attention.

With regard to such a method of manufacturing a substrate for a printed circuit board by applying and sintering a fine metal particle dispersion liquid, for example, in Japanese Laid-open Patent Publication No. 2006-228878, a coating film of a fine metal particle dispersion liquid (a dispersion of metal thin film precursor fine particles) is heat-treated by using a heating means such as a radiation heating furnace of far infrared, infrared, microwave, or electron beam, an electric furnace, or an oven. Also, the above described publication describes that it is preferable to perform the heat treatment of the coating film of the fine metal particle dispersion liquid in an inert atmosphere to suppress oxidation of the metal.

### PRIOR ART DOCUMENT

### Patent Document

[Patent Document 1] Japanese Laid-open Patent Publication No. 2006-228878

### SUMMARY OF THE INVENTION

### Means for Solving the Problem

According to one aspect of the present disclosure, a method of manufacturing a substrate for a printed circuit board including an insulating base film and a metal layer that is layered on at least one surface side of the base film, the method comprising: an application step of applying, to the at least one surface side of the base film, a dispersion liquid containing fine metal particles; a drying step of drying a coating film of the applied dispersion liquid; a sintering step of sintering the dried coating film by a far-infrared heater under a low oxygen atmosphere with an oxygen concentration of 600 ppm by volume or less; and a cooling step of cooling a layered structure of the sintered coating film and the base film under a low oxygen atmosphere with an oxygen concentration of 600 ppm by volume or less.

### BRIEF DESCRIPTION OF THE DRAWINGS

FIG. 1 is a flow chart illustrating a procedure of a method of manufacturing a substrate for a printed circuit board according to one embodiment of the present disclosure;

FIG. 2 is a schematic cross-sectional view illustrating a configuration of the substrate for a printed circuit board that is manufactured by the method of manufacturing the substrate for a printed circuit board of FIG. 1; and

FIG. 3 is a schematic diagram illustrating a configuration of a tunnel furnace that is used in the method of manufacturing the substrate for a printed circuit board of FIG. 1.

### EMBODIMENT FOR CARRYING OUT THE INVENTION

### Problem to Be Solved by the Present Disclosure

As disclosed in the above described publication, even in a case in which the coating film of a fine metal particle dispersion is heated in an inert gas using a far-infrared heater, oxidation of the metal layer may not be sufficiently suppressed, resulting in an occurrence of inconvenience such as insufficient adhesion of the metal layer to the base film.

In view of above, the present disclosure has an object to provide a method of manufacturing a substrate for a printed circuit board that enables to reliably suppress oxidation of a metal layer.

### Effect of the Present Disclosure

According to one aspect of the present disclosure, a method of manufacturing a substrate for a printed circuit board enables to suppress reliably suppress oxidation of a metal layer.

### Description of Embodiments of the Present Disclosure

According to one aspect of the present disclosure, a method of manufacturing a substrate for a printed circuit board including an insulating base film and a metal layer that is layered on at least one surface side of the base film, the method comprising: an application step of applying, to the at least one surface side of the base film, a dispersion liquid containing fine metal particles; a drying step of drying a coating film of the applied dispersion liquid; a sintering step of sintering the dried coating film by a far-infrared heater under a low oxygen atmosphere with an oxygen concentration of 600 ppm by volume or less; and a cooling step of cooling a layered structure of the sintered coating film and the base film under a low oxygen atmosphere with an oxygen concentration of 600 ppm by volume or less.

According to the method of manufacturing the substrate for a printed circuit board, by including the cooling step after the sintering step, the metal layer formed in the sintering step is sufficiently cooled under a low oxygen atmosphere to be in a stable state of less likely to be oxidized even when being in contact with air, and therefore, it is possible to reliably suppress oxidation of the metal layer.

In the method of manufacturing the substrate for a printed circuit board, cooled nitrogen gas may be supplied to a periphery of the layered structure in the cooling step. In this manner, by supplying the nitrogen gas cooled to the periphery of the layered structure in the cooling step, cooling of the metal layer can be promoted and oxidation of the metal layer can be suppressed more reliably.

In the method of manufacturing the substrate for a printed circuit board, the sintering step and the cooling step may be carried out continuously in a tunnel furnace including a heating space and a cooling space. In this manner, by continuously performing the sintering step and the cooling step in the tunnel furnace including the heating space and the cooling space, because the metal layer can be cooled under a low oxygen atmosphere without exposing the metal layer to a high oxygen atmosphere after the sintering, oxidation of the metal layer can be easily and reliably suppressed.

In the method of manufacturing the substrate for a printed circuit board, a furnace wall that defines the cooling space may be cooled with a coolant in the cooling step. In this manner, by cooling the furnace wall that defines the cooling space with the coolant in the cooling step, cooling of the metal layer can be promoted and oxidation of the metal layer can be suppressed more reliably.

In the method of manufacturing the substrate for a printed circuit board, a temperature of the sintered coating film is cooled to 100° C. or less in the cooling step. In this manner, by cooling the temperature of the sintered coating film, that is, the metal layer, to 100° C. or less in the cooling step, it is possible to make the metal layer a stable state of less likely to be oxidized more reliably.

### Details of Embodiments of the Present Disclosure

In the following, embodiments of a method of manufacturing a substrate for a printed circuit board according to the present disclosure will be described in detail with reference to the drawings.

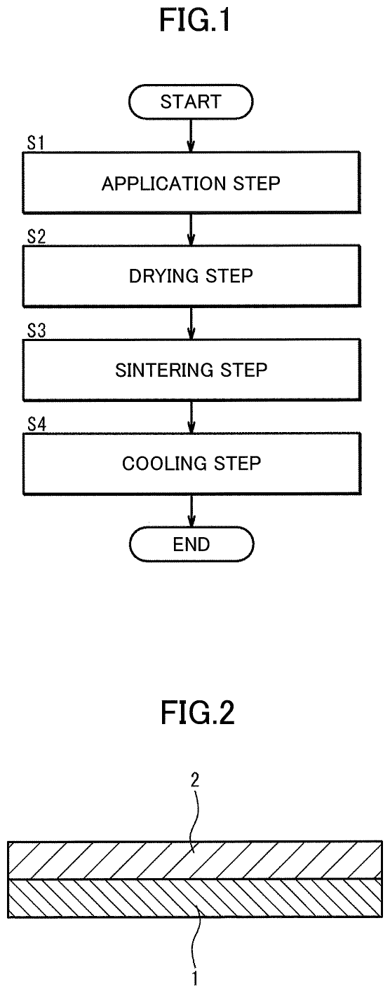

FIG. 1 illustrates a procedure of the method of manufacturing the substrate for a printed circuit board. The method of manufacturing the substrate for a printed circuit board is, as illustrated in FIG. 2, a method of manufacturing a substrate for a printed circuit board including an insulating base film 1 and a metal layer 2 that is layered on at least one surface side of the base film 1.

The method of manufacturing the substrate for a printed circuit board includes an application step of applying, to the at least one surface side of the base film 1, a dispersion liquid containing fine metal particles (step S1); a drying step of drying a coating film of the applied dispersion liquid (step S2); a sintering step of sintering the dried coating film by a far-infrared heater under a low oxygen atmosphere with an oxygen concentration (step S3); and a cooling step of cooling a layered structure of the sintered coating film and the base film 1 under a low oxygen atmosphere with an oxygen concentration (step S4).

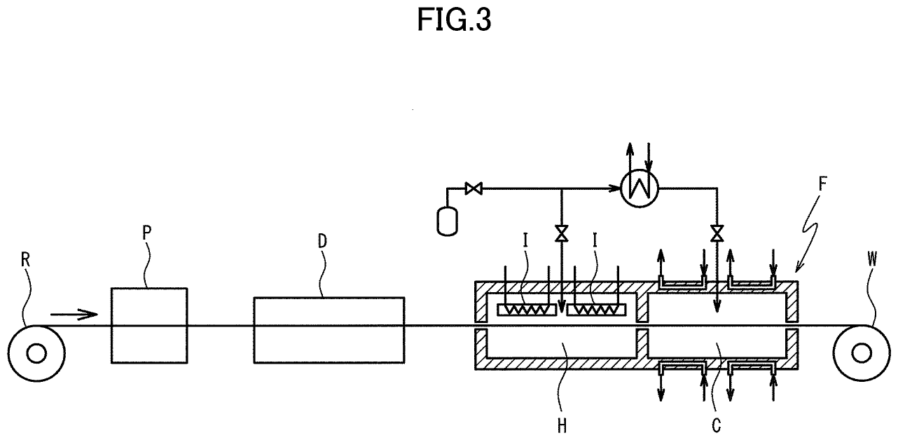

FIG. 3 illustrates an outline of a manufacturing facility of a substrate for a printed circuit board for carrying out the method of manufacturing the substrate for a printed circuit board.

The manufacturing facility includes a supply device R that continuously supplies the base film 1 formed in a long film form from a reel, an application device P that continuously performs the application step, a drying device D that continuously performs the drying step, a tunnel furnace F including a heating space H provided with far-infrared heaters I to continuously perform the sintering step and including a cooling space C that continuously performs the cooling step, and a winding device W that winds the obtained substrate for a printed circuit board onto a reel.

(Application Step)

In the application step at step S1, a fine metal particle dispersion liquid including fine metal particles formed from a metal material constituting the metal layer 2 is applied to the base film 1.

<Base Film 1>

Examples of a material of the base film 1 that can be used include a flexible resin such as a polyimide, a liquid crystal polymer, a fluorine resin, polyethylene terephthalate, and polyethylene naphthalate, a rigid material such as paper phenol, paper epoxy, glass composite, glass epoxy, polytetrafluoroethylene, and glass substrate, and a rigid flexible material in which a rigid material and a soft material are combined. Among these, because of having a high bonding strength with a metal oxide or the like, polyimide is particularly preferable.

The lower limit of the average thickness of the base film 1 is preferably 5 μm and is more preferably 12 μm. On the other hand, the upper limit of the average thickness of the base film 1 is preferably 2 mm and is more preferably 1.6 mm. In a case in which the average thickness of the base film 1 is less than the lower limit as described above, the strength of the base film 1 or the substrate for a printed circuit board may be insufficient. On the other hand, in a case in which the average thickness of the base film 1 exceeds the upper limit as described above, the substrate for a printed circuit board may be unnecessarily thick.

A modification process may be applied to the surface of the base film 1 prior to application of the dispersion liquid. For example, a plasma treatment, an alkali treatment, energy irradiation, or the like can be used as the modification process. By the modification process, the adhesion between the base film 1 and the metal layer 2 can be enhanced and application of the dispersion liquid can be facilitated. Also, on the surface of the base film 1, a thin layer may be layered in advance to enhance adhesion with the metal layer 2 that is formed by the dispersion liquid. Examples of a method of forming such a thin layer include electroless plating, application of a coupling agent, and the like.

<Fine Metal Particle Dispersion Liquid>

It is preferable to use, as the fine metal particle dispersion liquid, a liquid that includes fine metal particles that form the metal layer 2, a dispersion medium for the fine metal particles, and a dispersant for uniformly dispersing the fine metal particles in the dispersion medium. By using the dispersion liquid in which the fine metal particles are dispersed uniformly as described above, the fine metal particles can be uniformly adhered to the surface of the base film 1, and thus a metal layer 2 having a uniform thickness can be famed on the surface of the base film 1.

(Fine Metal Particles)

For example, copper (Cu), nickel (Ni), aluminum (Al), gold (Au), silver (Ag), or the like may be used as the main component of the fine metal particles. Among these, copper having low cost, excellent electrical conductivity, and excellent adhesion to the base film 1 is particularly preferably used as the main component of the fine metal particles.

The lower limit of the average particle size of the fine metal particles that form the metal layer 2 is preferably 1 nm and is more preferably 30 nm. On the other hand, the upper limit of the average particle size of the fine metal particles is preferably 500 nm and is more preferably 100 nm. In a case in which the average particle size of the fine metal particles is less than the lower limit as described above, for example, due to a decrease in dispersibility and stability of the fine metal particles in the fine metal particle dispersion liquid, uniform layering may not be easily performed on the surface of the base film 1. On the other hand, in a case in which the average particle size of the fine metal particles exceeds the upper limit as described above, gaps between the fine metal particles become larger and the porosity of the metal layer 2 may not be easily reduced.

(Dispersion Medium)

As the dispersion medium of the fine metal particle dispersion liquid, water or a mixture of water and a highly polar solvent can be used, in particular, a mixture of water and a highly polar solvent that is compatible with water is preferably used.

The content rate of water in the fine metal particle dispersion liquid is preferably greater than or equal to 20 parts by mass and less than or equal to 1900 parts by mass, per 100 parts by mass of the fine metal particles. Water in the dispersion medium sufficiently swells the dispersant to satisfactorily disperse the fine metal particles surrounded by the dispersant. However, in a case in which the content rate of the water is less than the lower limit, the swelling effect of the dispersant by the water may be insufficient. On the other hand, in a case in which the content rate of the water exceeds the upper limit, the content rate of the fine metal particles in the fine metal particle dispersion liquid decreases, and a favorable metal layer 2 having the required thickness and density may not be formed on the base film 1.

The highly polar solvent in the dispersion medium is preferably a volatile organic solvent that can evaporate in a short time at the time of sintering. By using the volatile organic solvent as the highly polar solvent, the highly polar solvent volatilizes in a short time at the time of sintering and the viscosity of the fine metal particle dispersion liquid applied to the surface of the base film 1 is rapidly increased without causing movement of the fine metal particles.

As such a volatile organic solvent, any of various organic solvents having volatility at room temperature (greater than or equal to 5° C. and less than or equal to 35° C.) can be used. Among these, for example, a volatile organic solvent having a boiling point greater than or equal to 60° C. to 140° C. at an ordinary pressure is preferable, and particularly, an aliphatic saturated alcohol whose carbon number is greater than or equal to 1 and less than or equal to 5 and having a high volatility and excellent compatibility with water is preferable.

Examples of the aliphatic saturated alcohol whose carbon number is greater than or equal to 1 and less than or equal to 5 include methyl alcohol, ethyl alcohol, n-propyl alcohol, isopropyl alcohol, n-butyl alcohol, isobutyl alcohol, sec-butyl alcohol, tert-butyl alcohol, n-amyl alcohol, isoamyl alcohol, and the like, and a mixture of one or more of these may be used.

The lower limit of the content rate of the volatile organic solvent in the total dispersion medium is preferably 30% by mass and is more preferably 40% by mass. On the other hand, the upper limit of the content rate of the volatile organic solvent in the total dispersion medium is preferably 80% by mass and is more preferably 70% by mass. In a case in which the content rate of the volatile organic solvent in the total dispersion medium is less than the lower limit as described above, the coating film may not become dense at the drying step. Also, in a case in which the content rate of the volatile organic solvent in the total dispersion medium exceeds the upper limit as described above, because the content rate of water is relatively low, the wettability of the fine metal particle dispersion liquid with respect to the surface of the base film 1 may be insufficient.

Examples of the highly polar solvent other than the volatile organic solvent include ethylene glycol, propylene glycol, glycerin, and the like, and a mixture of one or more of these is used. These highly polar solvents serve as a binder to prevent movement of the fine metal particles during sintering.

The lower limit of the content of the total dispersion medium in the fine metal particle dispersion liquid is preferably 100 parts by mass and is more preferably 400 parts by mass per 100 parts by mass of the metal particles. On the other hand, the upper limit of the content of the total dispersion medium in the fine metal particle dispersion liquid is preferably 3000 parts by mass and is more preferably 1000 parts by mass per 100 parts by mass of the metal particles. In a case in which the content of the total dispersion medium in the fine metal particle dispersion liquid is less than the lower limit as described above, the viscosity of the fine metal particle dispersion liquid increases, and application to the base film 1 may be difficult. Also, in a case in which the content of the total dispersion medium in the fine metal particle dispersion liquid exceeds the upper limit as described above, the viscosity of the fine metal particle dispersion liquid decreases, and a coating film with a sufficient thickness may not be formed.

(Dispersant)

Although the dispersant that is contained in the fine metal particle dispersion liquid is not particularly limited, a polymeric dispersant whose molecular weight is greater than or equal to 100 and less than or equal to 300,000 is preferably used. In this manner, by using the polymeric dispersant having a molecular weight within the range described above, it is possible to disperse the fine metal particles satisfactorily in the dispersion medium, and it is possible to make the film quality of the obtained metal layer 2 dense and defect-free. In a case in which the molecular weight of the dispersant is less than the lower limit, the effect of preventing the aggregation of the fine metal particles to maintain the dispersion may not be sufficiently obtained. As a result, a dense metal layer 2 having few defects may not be layered on the base film 1. On the other hand, in a case in which the molecular weight of the dispersant exceeds the upper limit, the dispersant may be excessively bulky, and in the sintering step, sintering of the fine metal particles may be inhibited and voids may be generated. Also, when the dispersant is excessively bulky, the denseness of the film quality of the metal layer 2 may be decreased, and the decomposition residues of the dispersant may decrease the conductivity.

To prevent the degradation of the metal layer 2, the dispersant preferably does not contain sulfur, phosphorus, boron, halogen, and alkali. Preferable examples of the dispersant, having a molecular weight within the range described above, include amine-based polymeric dispersants such as polyethyleneimine and polyvinylpyrrolidone; hydrocarbon-based polymeric dispersants having a carboxylic acid group in its molecule, such as polyacrylic acid and carboxymethyl cellulose; polymeric dispersants having a polar group, such as Poval (polyvinyl alcohol), styrene-maleic acid copolymers, olefin-maleic acid copolymers, and copolymers having a polyethyleneimine moiety and a polyethylene oxide moiety in one molecule thereof.

The content rate of the dispersant is preferably greater than or equal to 1 part by mass and less than or equal to 60 parts by mass per 100 parts by mass of the fine metal particles. Although the dispersant surrounds the fine metal particles to prevent aggregation of the fine metal particles, and satisfactorily disperses the fine metal particles, in a case in which the content rate of the dispersant is less than the lower limit, the effect of preventing the aggregation may be insufficient. On the other hand, in a case in which the content rate of the dispersant exceeds the upper limit, in the sintering step after applying the fine metal particle dispersion liquid, an excessive dispersant may inhibit sintering of the fine metal particles and voids may be generated. Further, the decomposition residues of the polymeric dispersant may remain as impurities in the metal layer to decrease the conductivity.

As a method of applying the fine metal particle dispersion liquid, for example, a known coating method, such as a spin coating method, a spray coating method, a bar coating method, a die coating method, a slit coating method, a roll coating method, or a dip coating method, can be used. Also, the fine metal particle dispersion liquid may be applied to only a part of the one surface of the base film 1 by screen printing, a dispenser, or the like.

<Drying step>

In the drying step of step S2, the coating film of the fine metal particle dispersion liquid on the base film 1 is dried. Here, by reducing the time from the application to the drying of the fine metal particle dispersion liquid, the metal layer 2 to be obtained by sintering the coating film in the subsequent sintering step can be made denser, that is, the area rate of sintered bodies of the fine metal particles in the cross section of the metal layer 2 can be increased.

In the drying step, it is preferable to promote drying of the fine metal particle dispersion liquid by heating or air blowing, and it is more preferable to dry the coating film by blowing hot air onto the coating film of the fine metal particle dispersion liquid. The temperature of the hot air is preferably such that the solvent of the fine metal particle dispersion liquid does not boil. A specific temperature of the hot air, for example, can be greater than or equal to 30° C. and less than or equal to 80° C. Also, it is preferable that the wind velocity of the hot air is such that the coating film is ruffled. For example, a specific wind velocity on the coating film surface of the hot air can be greater than or equal to 5 m/s and less than or equal to 10 m/s. Also, in order to reduce the time of drying the fine metal particle dispersion liquid, it is preferable to use a fine metal particle dispersion liquid of which solvent has a low boiling point.

<Sintering Step>

In the sintering step of step S3, the dried coating film formed by drying the coating film of the fine metal particle dispersion liquid on the base film 1 in the drying step is heated using the far-infrared heater I under a low oxygen atmosphere. As a result, the dispersant of the fine metal particle dispersion liquid is thermally decomposed, the remaining fine metal particles are sintered, and the metal layer 2 adhered to one surface of the base film 1 is obtained.

In this sintering step, by heating the dried coating film of the fine metal particle dispersion liquid under the low oxygen atmosphere, it is possible to suppress oxidation of the fine metal particles.

Thereby, it is possible to enhance the adhesion (peel strength) of the obtained metal layer 2 to the base film 1 and to prevent an increase in the electrical resistance of the metal layer 2.

In addition, in the sintering step, by using the far-infrared heater I, the dried coating film of the fine metal particle dispersion liquid can be heated to sinter the fine metal particles in a short period of time, and therefore, oxidation of the fine metal particles can be reliably prevented.

The low oxygen atmosphere in the sintering step can be obtained, for example, by replacing air by supplying a replacement gas, such as nitrogen gas, argon gas, or carbon dioxide gas, to the periphery of the layered structure of the base film 1 and the dried coating film of the fine metal particle dispersion liquid. Among these, it is preferable to use nitrogen gas that is relatively inexpensive and safe to form the low oxygen atmosphere.

In a case in which the dried coating film formed on the base film 1 in a long film form is continuously sintered using the tunnel furnace F, it is preferable to continuously supply a replacement gas to the heating space

H and maintain the oxygen concentration at a constant value because external air enters into the heating space H from the opening for supplying the base film 1 to the heating space H.

The lower limit of the oxygen concentration in the atmosphere at the time of sintering is preferably 1 ppm by volume, and is more preferably 10 ppm by volume. On the other hand, the upper limit of the oxygen concentration is preferably 600 ppm by volume, is more preferably 400 ppm by volume, and is further more preferably 300 ppm by volume. In a case in which the oxygen concentration is less than the lower limit as described above, the manufacturing facility may be expensive and the substrate for a printed circuit board may be unnecessarily expensive. On the other hand, in a case in which the oxygen concentration exceeds the upper limit as described above, due to oxidation of the fine metal particles, the conductivity of the metal layer 2 may decrease or the adhesion to the base film 1 may decrease.

The lower limit of the sintering temperature is preferably 200° C., and is more preferably 300° C. On the other hand, the upper limit of the sintering temperature is preferably 500° C., and is more preferably 400° C. In a case in which the sintering temperature is less than the lower limit as described above, because it takes a long time to sinter the fine metal particles, a slight amount of oxygen in the atmosphere may oxidize the fine metal particles. On the other hand, in a case in which the sintering temperature exceeds the upper limit as described above, the base film 1 may deform.

The lower limit of the sintering time is preferably 3 minutes and is more preferably 5 minutes. On the other hand, the upper limit of the sintering time is preferably 120 minutes and is more preferably 60 minutes. In a case in which the sintering time is less than the lower limit as described above, the fine metal particles may not be completely sintered. On the other hand, in a case in which the sintering time exceeds the above upper limit as described above, the cost of manufacturing the substrate for a printed circuit board may be unnecessarily increased because it is required to increase the length of the tunnel furnace F or reduce the conveyance speed of the layered structure.

<Cooling Step>

In the cooling step of step S4, the substrate for a printed circuit board obtained by forming the metal layer 2 on at least one surface side of the base film 1 by sintering is cooled under a low oxygen atmosphere without contact with outside air.

Hence, it is preferable that the cooling step is performed in the cooling space C that is continuously provided on the downstream side of the heating space H, at which the sintering step is performed, in the tunnel furnace F. That is, by continuously performing the sintering step and the cooling step using one tunnel furnace F including the heating space H and the cooling space C, the metal layer 2 is not exposed to gas having a high oxygen concentration after the sintering step, and it is possible to prevent oxidation of the metal layer 2 more reliably.

The lower limit of the oxygen concentration in the atmosphere at the time of cooling is preferably 1 ppm by volume, and is more preferably 10 ppm by volume. On the other hand, the upper limit of the oxygen concentration is preferably 600 ppm by volume, is more preferably 400 ppm by volume, and is further more preferably 300 ppm by volume. In a case in which the oxygen concentration is less than the lower limit as described above, the manufacturing facility may be expensive and the substrate for a printed circuit board may be unnecessarily expensive. On the other hand, in a case in which the oxygen concentration exceeds the upper limit as described above, due to oxidation of the fine metal particles, the conductivity of the metal layer 2 may decrease or the adhesion to the base film 1 may decrease.

In the cooling step, it is preferable to supply cooled nitrogen gas to the periphery (cooling space C) of a layered structure of the base film 1 and the sintered coating film, that is, the substrate for a printed circuit board. As a result, the oxygen concentration of the gas that comes into contact with the sintered coating film, that is, the metal layer 2 can be reliably kept low, and the temperature can be quickly lowered. As a result, oxidation of the metal layer 2 can be prevented more reliably.

The method of cooling the nitrogen gas, for example, can be a method of using a heat exchanger that exchanges heat with a coolant such as cold water or brine.

The lower limit of the temperature of the nitrogen gas that is supplied to the cooling space C (the temperature after cooling) is preferably 5° C. and is more preferably 10° C. On the other hand, the upper limit of the temperature of the nitrogen gas that is supplied to the cooling space C is preferably 100° C. and is more preferably 90° C. In a case in which the temperature of the nitrogen gas supplied to the cooling space C is less the lower limit as described above, the cost of manufacturing a substrate for a printed circuit board may unnecessarily increase because of a cooling device becoming expensive. On the other hand, in a case in which the temperature of the nitrogen gas that is supplied to the cooling space C exceeds the upper limit as described above, the temperature of the metal layer 2 may not be rapidly lowered.

In order to lower the temperature of the metal layer 2 more quickly, it is preferable that the furnace wall that defines the cooling space C is cooled by a coolant such as cooling water or brine.

In the cooling step, the temperature of the sintered coating film (the metal layer 2) is cooled to a temperature at which the metal is stable and is not easily oxidized. The lower limit of the cooling temperature (reaching temperature) is preferably 30° C. and is more preferably 40° C. On the other hand, the upper limit of the cooling temperature is preferably 100° C. and is more preferably 80° C. In a case in which the cooling temperature is less than the lower limit as described above, the cost of manufacturing of a substrate for a printed circuit board may increase unnecessarily. On the other hand, in a case in which the cooling temperature exceeds the upper limit as described above, oxidation of the metal layer 2 may not be sufficiently suppressed.

<Advantages>

According to the method of manufacturing the substrate for a printed circuit board, by including the cooling step after the sintering step, the metal layer formed in the sintering step is sufficiently cooled under a low oxygen atmosphere to be in a stable state of less likely to be oxidized even when being in contact with air, and therefore, it is possible to reliably suppress oxidation of the metal layer. Hence, in the substrate for a printed circuit board that is obtained by the method of manufacturing the substrate for a printed circuit board, the adhesion between the base film 1 and the metal layer 2 is high and the electrical resistance of the metal layer 2 is low.

### Other Embodiments

The embodiments disclosed above should be considered exemplary in all respects and not limiting. The scope of the present invention is not limited to configurations of the above described embodiments, but is indicated by claims and is intended to include all changes within the meaning and scope of equivalence with the claims.

In the method of manufacturing the substrate for a printed circuit board, the base film on which the dried coating film is formed after the drying step may be wound onto a reel once, and the base film on which the dried coating film is formed is supplied from the reel to a tunnel furnace or the like to carry out the sintering step and the cooling step.

In the method of manufacturing the substrate for a printed circuit board, the drying step may be performed in a device that performs the sintering step. As a specific example, a tunnel furnace having, at the upstream side of the sintering space for sintering the dried coating film, a drying space for drying the coating film may be used.

The method of manufacturing the substrate for a printed circuit board may use a device where a connection space for holding a low oxygen atmosphere is arranged between the heating space and the cooling space.

### EXAMPLES

Although the present invention will be described below in detail based on Examples, the present invention is not limited based on the description of the Examples.

<Prototypes of Base Materials for Printed Circuit Boards>In order to verify effects of the present disclosure, six types of prototypes No. 1 to No. 6 of base materials for printed circuit boards were manufactured with different manufacturing conditions.

(Prototype No. 1)

First, copper particles having an average particle size of 26 nm were used as metal particles and were dispersed in water of a solvent to prepare a copper particle dispersion liquid having a copper concentration of 30% by mass. Next, as a base film, a long polyimide film (“APICAL NPI” manufactured by Kaneka Corporation) having an average thickness of 25 μm and having an average width of 250 mm was used. The copper particle dispersion liquid was applied to one surface of the base film by a bar coating method, and the coating film was dried by applying warm air with a wind velocity of 7 m/s and a temperature of 25° C. in the vertical direction to the film surface, a dried coating film was similarly formed on the opposite side surface, and it was wound onto a reel.

Subsequently, using a tunnel furnace having an interior space of 105 cm in width and 20 cm in height, the interior space being divided into a heating space of 4.0 m in length and a cooling space of 1.0 m in length, the base film on which the dried coating film were formed was continuously sintered and cooled at a conveyance speed of 0.4 m/min, thereby preparing prototype No. 1 of a substrate for a printed circuit board.

In the heating space, at a position 10 cm away from the film conveyance surface, a far-infrared heater with a width of 80 cm, a total length of 360 cm, and a total output of 57.6 kW was installed. The output of the far-infrared heater was controlled so that the temperature in the heating space was 350° C. Also, to the heating space, nitrogen gas was supplied from multiple points at a total flow rate of 1100 L/min. As a result, the sintering time was 10 min and the oxygen concentration in the heating space was 200 ppm by volume.

A coolant flow passage was provided in the furnace wall defining the cooling space, and cooling water of 10° C. was supplied to the coolant flow passage at a flow rate of 20 L/min. Also, to the cooling space, nitrogen gas cooled to 10° C. by a heat exchanger was supplied from multiple points at a total flow rate of 110 L/min. As a result, the cooling time was 3 min, the temperature of the base film at the time of being ejected from the cooling space was 50° C., and the oxygen concentration in the cooling space was 200 ppm by volume.

(Prototype No. 2)

With the exception of setting the conveyance speed to 0.2 m/min to set the sintering time to 20 min and the cooling time to 5 min, prototype No. 2 of a substrate for a printed circuit board was prepared under conditions similar to those for prototype No. 1 of the substrate for a printed circuit board.

(Prototype No. 3)

By setting the total amount of nitrogen gas supplied to the heating space to 900 L/min, the oxygen concentration in the heating space was set to 400 ppm by volume, and by setting the total amount of nitrogen gas supplied to the cooling space to 110 L/min, the oxygen concentration in the cooling space was set to 400 ppm by volume. Other than that, prototype No. 3 of a substrate for a printed circuit board was prepared under conditions similar to those for prototype No. 2 of the substrate for a printed circuit board.

(Prototype No. 4)

With the exception of setting the total amount of nitrogen gas supplied to the heating space to 650 L/min to set the oxygen concentration in the heating space to 800 ppm by volume and setting the total amount of nitrogen gas supplied to the cooling space to 110 L/min to set the oxygen concentration in the cooling space to 800 ppm by volume, prototype No. 4 of a substrate for a printed circuit board was prepared under conditions similar to those for prototype No. 2 of the substrate for a printed circuit board.

(Prototype No. 5)

With the exception of extending the length of the cooling space of the tunnel furnace to 2.4 m and stopping the supply of cooling water to the furnace wall that defines the cooling space so that the temperature of the base film at the time of being ejected from the cooling space was 70° C., prototype No. 5 of a substrate for a printed circuit board was prepared under conditions similar to those for prototype No. 2 of the substrate for a printed circuit board.

(Prototype No. 6)

With the exception of stopping the supply of cooling water to the furnace wall that defines the cooling space so that the temperature of the base film at the time of being ejected from the cooling space was 120° C., prototype No. 6 of a substrate for a printed circuit board was prepared under conditions similar to those for prototype No. 2 of the substrate for a printed circuit board.

<Evaluation>

For each of the prototypes No. 1 to No. 6 of the substrates for printed circuit boards, the thickness of the formed metal layer, the specific electrical resistance of the metal layer, the chromaticity b* of the metal layer surface, the copper oxide content rate of the metal layer, and the adhesion between the metal layer and the base film were measured.

(Thickness)

The thickness of the metal layer was measured using “SFT9300” manufactured by Hitachi High-Tech Corporation.

(Specific Electrical Resistance)

The specific electrical resistance of the metal layer was measured using “MCP-T600” manufactured by Mitsubishi Chemical Corporation.

(Chromaticity b*)

The chromaticity b* of the metal layer surface was measured using “CR-20” manufactured by Konica Minolta, Inc.

(Copper Oxide Content Rate)

The copper oxide content rate of the metal layer was measured by X-ray diffraction using “X'Pert” manufactured by Panalytical Ltd.

(Adhesion)

The adhesion between the metal layer and the base film was measured using “Autograph AGS-X” manufactured by Shimadzu Corporation by a method of peeling the conductor layer in the direction of 180 degrees with respect to the base film as the peel strength in accordance with JIS-C6471 (1995).

In the following table, for each of prototypes No. 1 to No. 6, the thickness of the metal layer, the specific electrical resistance of the metal layer, the chromaticity b* of the metal layer surface, the copper oxide content rate of the metal layer, and the adhesion between the metal layer and the base film are indicated. It should be noted that “>1000” for the specific electrical resistance means that the measured value is a large value exceeding 1000 μΩ·cm, which is the upper limit of the measurement range.

TABLE 1

| | PROTOTYPE NUMBER | | | | | |
|---|---|---|---|---|---|---|
| | No. 1 | No. 2 | No. 3 | No. 4 | No. 5 | No. 6 |
| THICKNESS [μm] | 0.21 | 0.0 | 0.19 | 0.21 | 0.18 | 0.21 |
| SPECIFIC | 5.4 | 4.3 | 5.6 | >1000 | 6.0 | 9.2 |
| ELECTRICAL | | | | | | |
| RESISTANCE | | | | | | |
| [μΩ · cm] | | | | | | |
| CHROMATICITY b * | 6.0 | 6.3 | 6.1 | 1.5 | 5.6 | 2.9 |
| COPPER OXIDE | 0 | 0 | 7 | 22 | 5 | 12 |
| CONTENT RATE | | | | | | |
| [wt %] | | | | | | |
| ADHESION | 7.0 | 8.5 | 7.1 | 0.0 | 7.1 | 5.5 |
| [N/cm] | | | | | | |

As indicated by this table, the prototype No. 4, which was sintered and cooled in an atmosphere with a relatively high oxygen concentration, had a high copper oxide content rate of the metal layer and a very low adhesion between the metal layer and the base film. Also, it was confirmed that oxidation of the metal layer can be further reduced by supplying cooled nitrogen gas to the cooling space, and oxidation of the metal layer can be further more reduced by cooling the furnace wall defining the cooling space with cooling water.

### DESCRIPTION OF THE REFERENCE NUMERALS

1 base film
2 metal layer
C cooling space
D drying device
F tunnel furnace
H heating space
I far-infrared heater
P application device
R supply device
W winding device
S1 application step
S2 drying step
S3 sintering step
S4 cooling step

1. A method of manufacturing a substrate for a printed circuit board including an insulating base film and a metal layer that is layered on at least one surface side of the base film, the method comprising:
applying, to the at least one surface side of the base film, a dispersion liquid containing fine metal particles;
drying a coating film of the applied dispersion liquid;
sintering the dried coating film by a far-infrared heater under a low oxygen atmosphere with an oxygen concentration of 600 ppm by volume or less; and
cooling a layered structure of the sintered coating film and the base film under a low oxygen atmosphere with an oxygen concentration of 600 ppm by volume or less.

2. The method of manufacturing the substrate for a printed circuit board according to claim 1, wherein cooled nitrogen gas is supplied to a periphery of the layered structure in the cooling.

3. The method of manufacturing the substrate for a printed circuit board according to claim 1, wherein the sintering and the cooling are carried out continuously in a tunnel furnace including a heating space and a cooling space.

4. The method of manufacturing the substrate for a printed circuit board according to claim 1, wherein a furnace wall that defines a cooling space is cooled with a coolant in the cooling.

5. The method of manufacturing the substrate for a printed circuit board according to claim 1, wherein a temperature of the sintered coating film is cooled to 100° C. or less in the cooling.
